(19) United States
(12) Patent Application Publication
(10) Pub. No.: US 2026/0073990 A1
(43) Pub. Date: Mar. 12, 2026

(54) NONVOLATILE MEMORY DEVICE AND METHOD OF OPERATING THE SAME

(71) Applicant: Samsung Electronics Co., Ltd., Suwon-si (KR)

(72) Inventors: YONGHYUK CHOI, Suwon-si (KR); JONGMIN KIM, Suwon-si (KR); SEUNGYONG CHOI, Suwon-si (KR); KWANGHO CHOI, Suwon-si (KR)

(21) Appl. No.: 19/223,404

(22) Filed: May 30, 2025

(30) Foreign Application Priority Data
Sep. 6, 2024 (KR) 10-2024-0121475

(51) Int. Cl. G11C 16/10; G11C 16/04

(52) U.S. Cl. CPC G11C 16/10; G11C 16/0483

(57) ABSTRACT

A nonvolatile memory device which includes a memory cell array and a control circuit. The memory cell array includes a target memory block and a non-target memory block. The control circuit starts a program operation on a target memory cell, and the program operation includes a plurality of program loops. The control circuit performs a channel equalization operation of equalizing a channel voltage of a cell string associated with the target memory cell, in response to receiving a suspend command according to a read request for one of the target memory block and the non-target memory block before a bit line setup operation of each of the plurality of program loops is completed and receiving a resume command according to the suspend command.

### CROSS-REFERENCE TO RELATED APPLICATIONS

This application claims priority under 35 U.S.C. § 119 to Korean Patent Application No. 10-2024-0121475 filed on Sep. 6, 2024, in the Korean Intellectual Property Office, the disclosure of which is incorporated by reference herein in its entirety.

### BACKGROUND

Embodiments of the present disclosure described herein relate to a semiconductor memory device, and more particularly, relate to a nonvolatile memory device and a method of operating the nonvolatile memory device.

Currently, an electronic device which includes a plurality of memory systems each including a nonvolatile memory device is being widely used. The nonvolatile memory device has the following advantages: excellent stability, excellent endurance, low power consumption, and a very fast speed at which information is accessed.

When a read request is received from a host device while the nonvolatile memory device performs a program operation, the nonvolatile memory device may suspend the program operation, may then complete the execution of a read operation according to the read request, and may then resume the suspended program operation. The reliability of data stored in the nonvolatile memory device is reduced due to the suspend and resume operations which are repeated while the program operation is performed, and power consumption increases due to the suspend operation, the resume operation, and the execution of a plurality of operations associated with the suspend and resume operations.

### SUMMARY

Embodiments of the present disclosure provide a nonvolatile memory device preventing the decrease in the reliability of data due to iteration of a suspend operation and a resume operation while a program operation is performed and reducing power consumption.

Embodiments of the present disclosure provide a method of operating the nonvolatile memory device.

According to an embodiment, a nonvolatile memory device includes a memory cell array and a control circuit. The memory cell array includes a target memory block and a non-target memory block. The target memory block includes a target memory cell, and the non-target memory block includes a non-target memory cell. The control circuit starts a program operation on the target memory cell. The program operation includes a plurality of program loops each including a bit line setup operation and a program execution operation. The control circuit performs a channel equalization operation of equalizing a channel voltage of a cell string associated with the target memory cell, in response to receiving a suspend command according to a read request for one of the target memory block and the non-target memory block before the bit line setup operation of each of the plurality of program loops is completed and receiving a resume command according to the suspend command.

According to an embodiment, in a nonvolatile memory device, a program operation on a target memory cell is started. The program operation includes a plurality of program loops each including a bit line setup operation and a program execution operation. There is received a suspend command according to a read request for one of a target memory block including the target memory cell and a non-target memory block including a non-target memory cell before the bit line setup operation of each of the plurality of program loops is completed. A resume command according to the suspend command is received. A channel equalization operation of equalizing a channel voltage of a cell string associated with the target memory cell in response to the suspend command and the resume command is performed.

According to an embodiment, a nonvolatile memory device includes a memory cell array, an address decoder, and a control circuit. The memory cell array includes a target memory block and a non-target memory block. The target memory block includes a target memory cell, and a non-target memory block includes a non-target memory cell. The address decoder is connected to the memory cell array through a string selection line, a plurality of word lines, and a ground selection line.

The control circuit starts a program operation on the target memory cell, and the program operation includes a plurality of program loops each including a bit line setup operation. A channel equalization operation of equalizing a channel voltage of a cell string associated with the target memory cell by controlling voltage levels of the string selection line, the plurality of word lines, and the ground selection line is performed in response to receiving a suspend command according to an operation request for one of the target memory block and the non-target memory block before the bit line setup operation of each of the plurality of program loops is completed and receiving a resume command according to the suspend command.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory system including a nonvolatile memory device according to an embodiment of the present disclosure.

FIGS. 2A and 2B are diagrams for describing a program operation on a memory block of a nonvolatile memory device of FIG. 1.

FIG. 3 is a block diagram illustrating a nonvolatile memory device of FIG. 1.

FIG. 4 is a block diagram illustrating an embodiment of a memory cell array of a nonvolatile memory device of FIG. 3.

FIG. 5 is a block diagram illustrating an embodiment of a memory block of FIG. 4.

FIG. 6 is a circuit diagram illustrating an embodiment of a memory block of FIG. 4.

FIG. 7 is a flowchart illustrating a method of operating a nonvolatile memory device according to an embodiment of the present disclosure.

FIG. 8 is a diagram for describing an embodiment of a channel equalization operation of FIG. 7.

FIG. 9 is a timing diagram for describing a channel equalization operation of FIG. 8.

FIG. 10 is a diagram for describing an embodiment of a channel equalization operation of FIG. 7.

FIG. 11 is a timing diagram for describing a channel equalization operation of FIG. 10.

FIG. 12 is a flowchart illustrating a method of operating a nonvolatile memory device according to an embodiment of the present disclosure.

FIG. 13 is a diagram for describing an embodiment in which a channel equalization operation of FIG. 12 is not performed.

FIG. 14 is a timing diagram for describing non-execution of a channel equalization operation of FIG. 13.

FIG. 15 is a diagram for describing an embodiment of a channel equalization operation of FIG. 12.

FIG. 16 is a flowchart for describing an embodiment of a channel equalization operation of FIG. 12.

FIG. 17 is a timing diagram for describing a channel equalization operation of FIG. 16.

FIG. 18 is a flowchart illustrating a method of operating a nonvolatile memory device according to an embodiment of the present disclosure.

FIG. 19 is a block diagram illustrating a memory system including a nonvolatile memory device according to an embodiment of the present disclosure.

FIG. 20 is a flowchart illustrating an operation of a control circuit of FIG. 19.

FIG. 21 is a block diagram illustrating a system to which a nonvolatile memory device according to embodiments of the present disclosure is applied.

### DETAILED DESCRIPTION

Below, embodiments of the present disclosure will be described in detail and clearly to such an extent that one skilled in the art easily carries out the present disclosure.

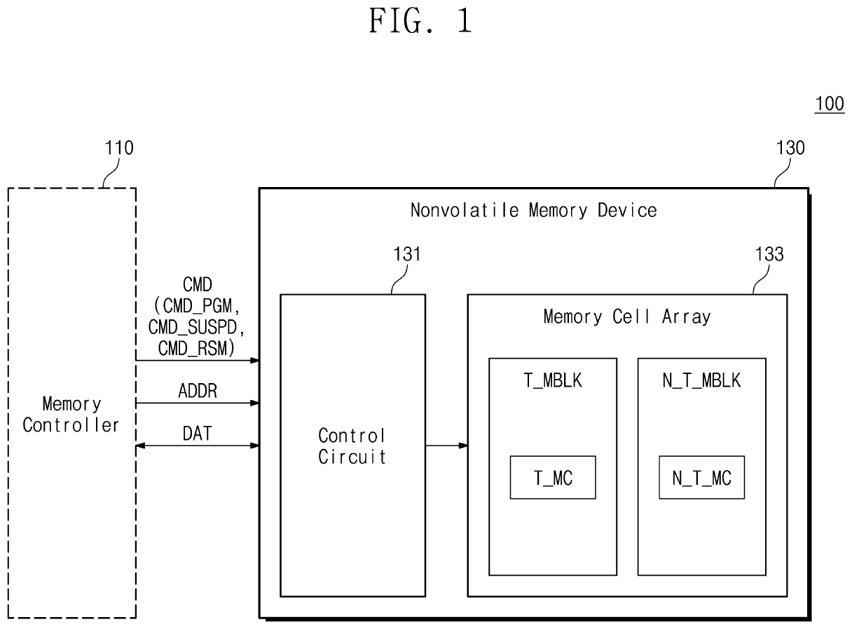

FIG. 1 is a block diagram illustrating a memory system including a nonvolatile memory device according to an embodiment of the present disclosure.

Referring to FIG. 1, a memory system 100 may include a memory controller 110 and a nonvolatile memory device 130. The nonvolatile memory device 130 may include a control circuit 131 and a memory cell array 133.

The memory controller 110 may send a command CMD and an address ADDR to the nonvolatile memory device 130 and may exchange data DAT with the nonvolatile memory device 130 based on the command CMD and the address ADDR.

The control circuit 131 may overall control the memory cell array 133; for example, based on the command CMD and the address ADDR from the memory controller 110, the control circuit 131 may program data in the memory cell array 133, may read data from the memory cell array 133, or may erase data stored in the memory cell array 133.

In an embodiment, the command CMD may include a program command CMD_PGM for performing the program operation of programming the data DAT in the nonvolatile memory device 130, a suspend command CMD_SUSPD for suspending the program operation when the read request is received from an external host device while performing the program operation, and a resume command CMD_RSM for resuming the suspended program operation after the execution of the read operation according to the read request is completed. The command CMD may further include a read command for reading data stored in the nonvolatile memory device 130 or an erase command for erasing data stored in the nonvolatile memory device 130, and may further include various commands for improving or maintaining the reliability of data stored in the nonvolatile memory device 130.

For convenience of description, a memory block of the memory cell array 133 may be referred to as a “target memory block T_MBLK” or a “non-target memory block N_T_MBLK”, and a memory cell of the memory cell array 133 may be referred to as a “target memory cell T_MC” or a “non-target memory cell N_T_MC”. Below, a memory cell targeted for the program operation is referred to as the “target memory cell T_MC”, and a memory cell not targeted for the program operation is referred to as the “non-target memory cell N_T_MC”. Regardless of the program operation, both the target memory cell T_MC and the non-target memory cell N_T_MC may be targeted for the read operation. In the target memory cell T_MC and the non-target memory cell N_T_MC, even though the expression “cell” is used, the program operation and the read operation on the nonvolatile memory device 130 (or the memory cell array 133) may be performed in units of page. A memory block including the target memory cell T_MC is referred to as the “target memory block T_MBLK”, and a memory block including the non-target memory cell N_T_MC is referred to as the “non-target memory block N_T_MBLK”.

The control circuit 131 may perform a channel equalization operation in response to a suspend command and a resume command issued in a specific time interval after the program operation on the target memory cell T_MC is started and before the program operation is completed.

In an embodiment, the program operation may include a plurality of program loops, and each of the plurality of program loops may include a bit line setup operation and a program execution operation. The bit line setup operation may refer to an operation of applying a ground voltage or a voltage greater than the ground voltage to bit lines associated with the target memory cell T_MC before the program execution operation, and the program execution operation may refer to an operation of applying a program voltage to the target memory cell T_MC. The control circuit 131 may perform the channel equalization operation of equalizing a channel voltage of a cell string associated with the target memory cell T_MC, in response to receiving the suspend command according to the read request for one of the target memory block T_MBLK and the non-target memory block N_T_MBLK before the bit line setup operation of each of the plurality of program loops is completed and receiving the resume command according to the suspend command. For example, the cell string may be connected between a bit line and a common source line and may have a structure in which memory cells including the target memory cell T_MC are connected in series between a string selection transistor and a ground selection transistor. The channel equalization operation may mean an operation of uniformly adjusting a channel voltage on a channel path formed in the direction of the string selection transistor (or bit line) based on the target memory cell T_MC and a channel voltage on a channel path formed in the direction of the ground selection transistor (or common source line) based on the target memory cell T_MC, and the voltage imbalance caused in the channel voltage of the cell string associated with the target memory cell T_MC as the suspend and resume operations are repeated while performing the program operation may be removed (or solved) by the channel equalization operation.

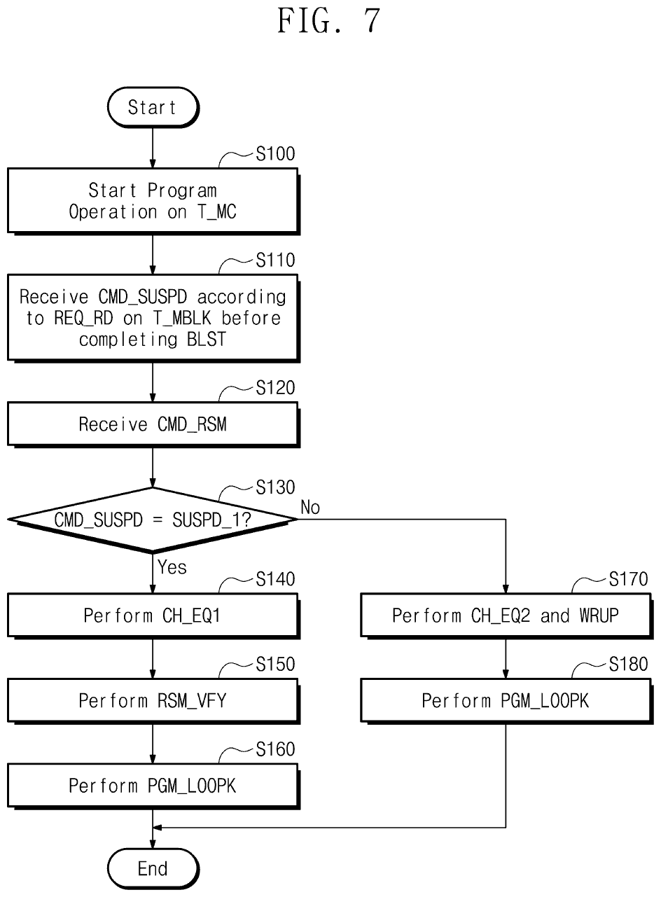

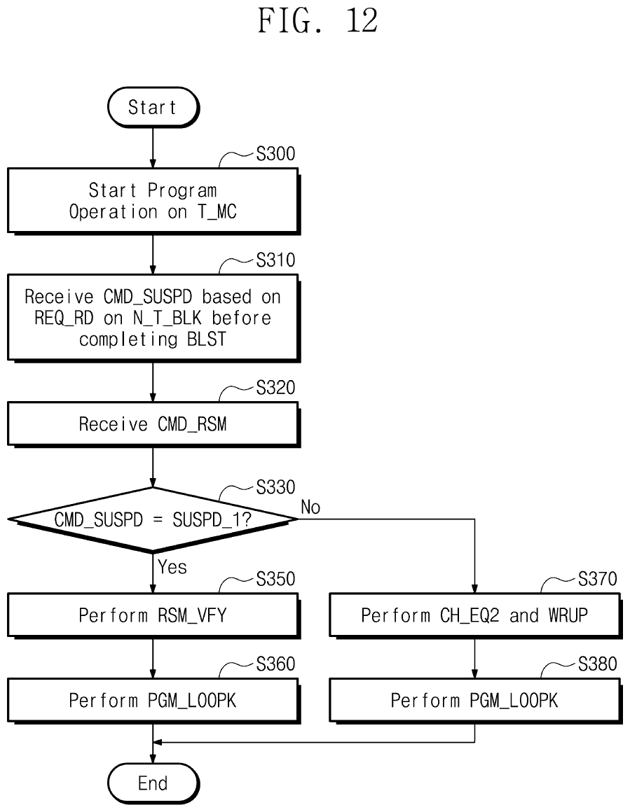

In an embodiment, the suspend command and the resume command may be issued by the read request from the external host device while performing the program operation. A nonvolatile memory device according to embodiments of the present disclosure may perform the channel equalization operation in different methods depending on whether the read request is a read request for the target memory cell T_MC (or the target memory block T_MBLK) or a read request for the non-target memory cell N_T_MC (or the non-target memory block N_T_MBLK). The channel equalization operation will be described with reference to FIGS. 7 and 12.

In an embodiment, the nonvolatile memory device according to embodiments of the present disclosure may perform the channel equalization operation in different methods depending on whether the suspend command according to the read request is firstly received during the execution of the program operation or is received secondly or later during the execution of the program operation. The channel equalization operation associated with the above description will be described with reference to FIGS. 7 to 11 and 12 to 15.

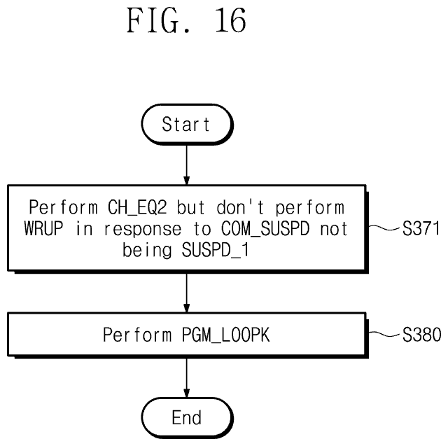

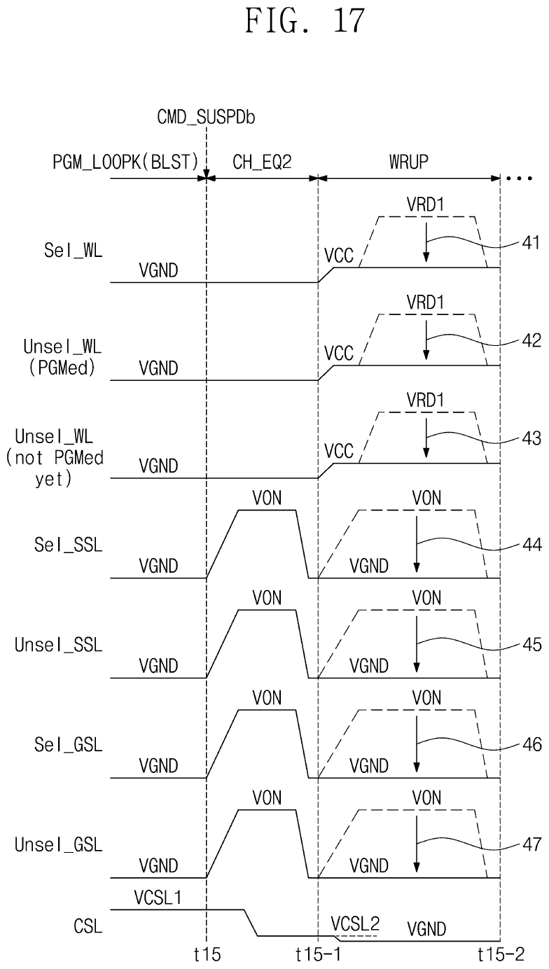

In an embodiment, the nonvolatile memory device 130 may further perform a wrapping up operation associated with the target memory cell T_MC depending on the suspend command, and the nonvolatile memory device according to embodiments of the present disclosure may not perform the wrapping up operation under a specific condition. The wrapping up operation will be described with reference to FIGS. 16 and 17.

Through the above configuration, the nonvolatile memory device according to embodiments of the present disclosure may remove the voltage imbalance caused in a channel voltage of a cell string due to the iteration of a suspend operation and resume operations according to the read request from the host device while performing the program operation. Accordingly, it may be possible to prevent the decrease in the reliability of data stored in the nonvolatile memory device and to reduce power consumption.

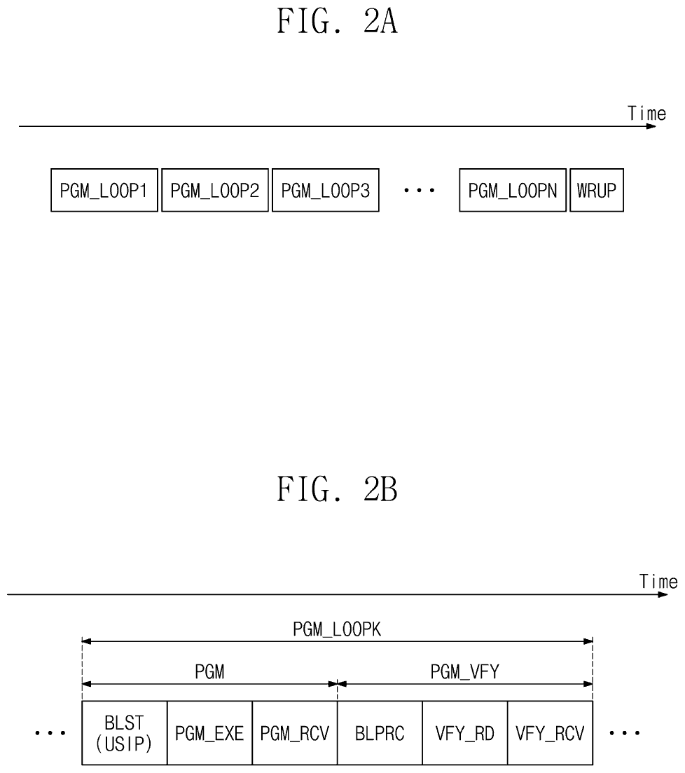

FIGS. 2A and 2B are diagrams for describing a program operation on a memory block of a nonvolatile memory device of FIG. 1.

Referring to FIG. 2A, the program operation may include a plurality of program loops PGM_LOOP1, PGM_LOOP2, PGM_LOOP3, . . . , PGM_LOOPN (N being an integer of 4 or more), and the plurality of program loops PGM_LOOP1, PGM_LOOP2, PGM_LOOP3, . . . , PGM_LOOPN may sequentially progress in the program operation. In the plurality of program loops PGM_LOOP1, PGM_LOOP2, PGM_LOOP3, . . . , PGM_LOOPN, a program voltage which stepwise increases in an incremental step pulse programming (ISPP) manner may be applied to a target memory cell.

The program operation may further include the wrapping up operation WRUP for performing a post operation on the target memory cell T_MC after the last program loop PGM_LOOPN among the plurality of program loops PGM_LOOP1, PGM_LOOP2, PGM_LOOP3, . . . , PGM_LOOPN.

Referring to FIGS. 2A and 2B, the program loop PGM_LOOPK (K being an integer of 1 or more and N or less) may be one of the plurality of program loops PGM_LOOP1, PGM_LOOP2, PGM_LOOP3, . . . , PGM_LOOPN. The program loop PGM_LOOPK may include a program interval PGM and a program verify interval PGM_VFY. In the program interval PGM, a bit line setup operation BLST, a program execution operation PGM_EXE, and a program recovery operation PGM_RCV may be sequentially performed; in the program verify interval PGM_VFY, a bit line pre-charge operation BLPRC, a verify read operation VFY_RD, and a verify recovery operation VFY_RCV may be sequentially performed.

In an embodiment, an unselect string initial pre-charge (USIP) operation for initializing a channel voltage of a cell string may be performed together with the bit line setup operation BLST.

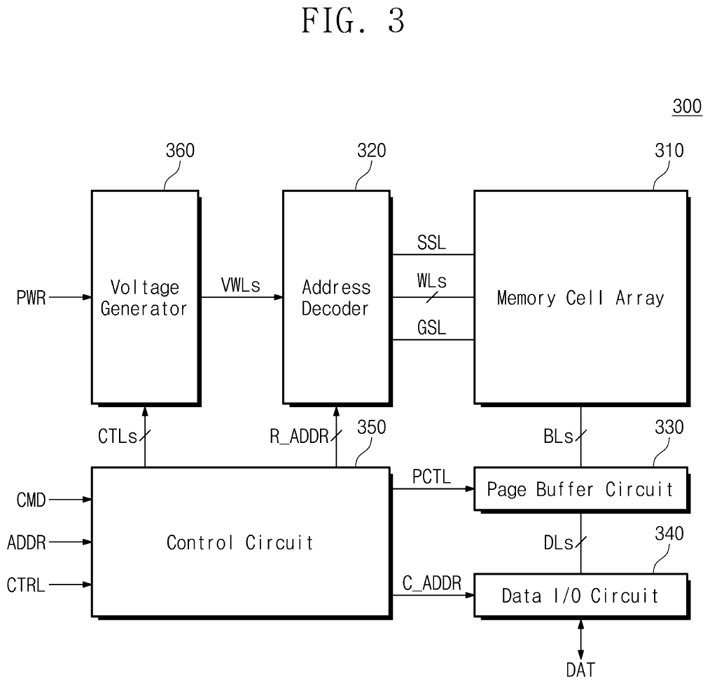

FIG. 3 is a block diagram illustrating a nonvolatile memory device of FIG. 1.

Referring to FIG. 3, a nonvolatile memory device 300 may include a memory cell array 310, an address decoder 320, a page buffer circuit 330, a data input/output circuit 340, a control circuit 350, and a voltage generator 360.

The memory cell array 310 may be connected to the address decoder 320 through a string selection line SSL, a plurality of word lines WLs, and a ground selection line GSL. Also, the memory cell array 310 may be connected to the page buffer circuit 330 through a plurality of bit lines BLs. The memory cell array 310 may include a plurality of memory cells connected to the plurality of word lines WLs and the plurality of bit lines BLs.

In an embodiment, the memory cell array 310 may be a three-dimensional (3D) memory cell array formed on a substrate in a 3D (or vertical) structure. In this case, the memory cell array 310 may include vertical memory cell strings including a plurality of memory cells stacked and formed.

The control circuit 350 may receive a control signal CTRL, a power signal PWR, the command CMD, and the address ADDR from a memory controller and may control the program loop, the read operation, and the erase operation of the nonvolatile memory device 300 based on the control signal CTRL, the power signal PWR, the command CMD, and the address ADDR.

For example, the control circuit 350 may generate control signals CTLs for controlling the voltage generator 360 and a page buffer control signal PCTL for controlling the page buffer circuit 330 based on the command CMD, and may generate a row address R_ADDR and a column address C_ADDR based on the address ADDR. The control circuit 350 may provide the row address R_ADDR to the address decoder 320 and may provide the column address C_ADDR to the data input/output circuit 340.

The address decoder 320 may be connected to the memory cell array 310 through the string selection line SSL, the plurality of word lines WLs, and the ground selection line GSL. In the program operation or the read operation, based on the row address R_ADDR from the control circuit 350, the address decoder 320 may determine one of the plurality of word lines WLs as a selected word line and may determine the remaining word lines among the plurality of word lines WLs other than the selected word line as unselected word lines.

The voltage generator 360 may generate word line voltages VWLs necessary for the operation of the nonvolatile memory device 300 based on the control signals CTLs provided from the control circuit 350. The word line voltages VWLs generated from the voltage generator 360 may be applied to the plurality of word lines WLs through the address decoder 320.

For example, in the erase operation, the voltage generator 360 may generate an erase voltage to be applied to a well of a memory block and may generate a word line erase voltage (i.e., a ground voltage) to be applied to all the word lines of the memory block. In the erase verify operation, the voltage generator 360 may generate an erase verify voltage to be applied to all the word lines of one memory block or to be applied in units of word line.

For example, in the program operation, the voltage generator 360 may generate a program voltage to be applied to the selected word line and may generate a program pass voltage to be applied to the unselected word lines. Also, in the program verify operation, the voltage generator 360 may generate a program verify voltage to be applied to the selected word line and may generate a verify pass voltage to be applied to the unselected word lines. In addition, in the read operation, the voltage generator 360 may generate a read voltage to be applied to the selected word line and may generate a read pass voltage to be applied to the unselected word lines.

The page buffer circuit 330 may be connected to the memory cell array 310 through the plurality of bit lines BLs. The page buffer circuit 330 may include a plurality of page buffers. The page buffer circuit 330 may temporarily store data to be programmed at a selected page in the program operation or data read from the selected page in the read operation.

The data input/output circuit 340 may be connected to the page buffer circuit 330 through a plurality of data lines DLs. In the program operation, the data input/output circuit 340 may receive the data DAT from the memory controller and may provide the data DAT to the page buffer circuit 330 based on the column address C_ADDR provided from the control circuit 350. In the read operation, the data input/output circuit 340 may provide the memory controller with the data DAT stored in the page buffer circuit 340 based on the column address C_ADDR provided from the control circuit 350.

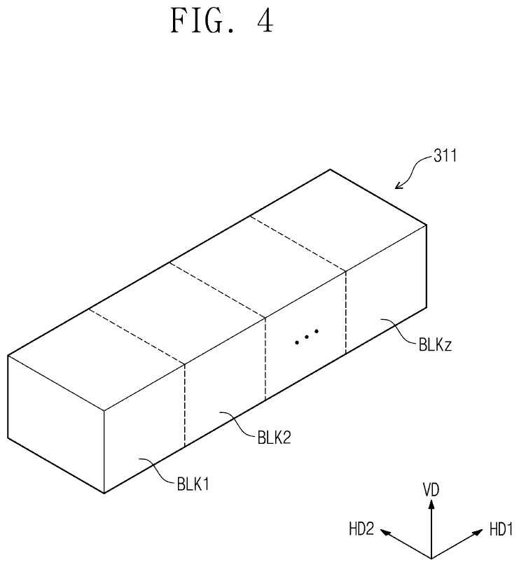

FIG. 4 is a block diagram illustrating an embodiment of a memory cell array of a nonvolatile memory device of FIG. 3.

Referring to FIG. 4, a memory cell array 311 may include a plurality of memory blocks BLK1, BLK2, . . . , BLKz (z being an integer of 3 or more) disposed along a first horizontal direction HD1, a second horizontal direction HD2, and a vertical direction VD. In an embodiment, memory blocks may be selected by the address decoder 320 of FIG. 3. For example, the address decoder 320 may select a memory block corresponding to a block address from among the plurality of memory blocks BLK1 to BLKz.

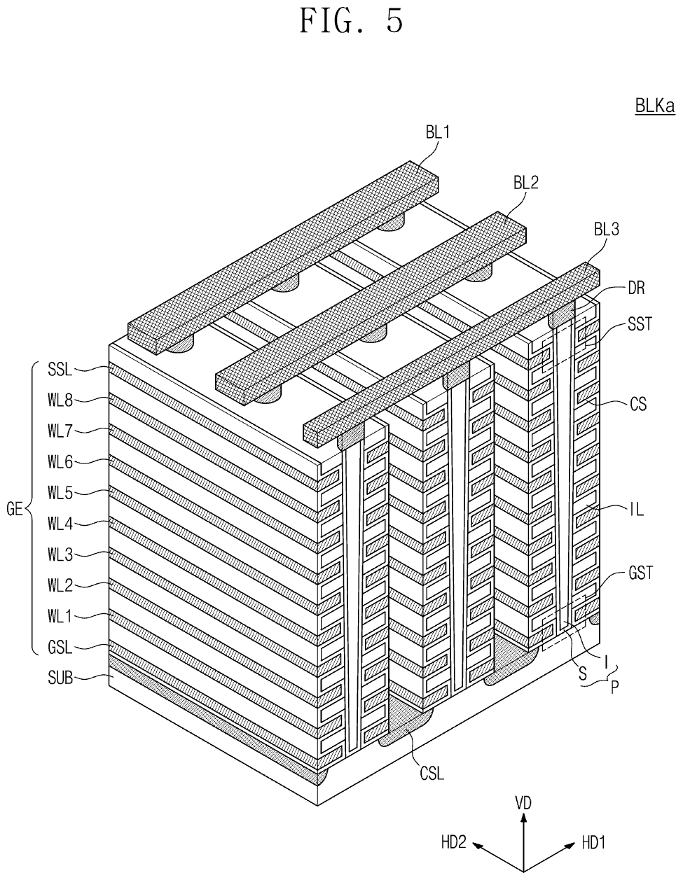

FIG. 5 is a block diagram illustrating an embodiment of a memory block of FIG. 4.

Referring to FIG. 5, a memory block BLKa may correspond to one of the plurality of memory blocks BLK1 to BLKz of FIG. 4. The memory block BLKa may be formed in a direction perpendicular to a substrate SUB. The substrate SUB is of a first conductivity type (e.g., a p-type), and a common source line CSL which extends along the second horizontal direction HD2 and is doped with impurities of a second conductivity type (e.g., an n-type) is provided on the substrate SUB. On a region of the substrate SUB between two adjacent common source lines CSL, a plurality of insulating layers IL which extend along the second horizontal direction HD2 are sequentially provided along the vertical direction VD, and the plurality of insulating layers IL are spaced apart from each other along the vertical direction VD as much as a specific distance. For example, each of the plurality of insulating layers IL may include an insulating material such as silicon oxide.

A plurality of pillars “P” which are sequentially disposed along the first horizontal direction HD1 and penetrate the plurality of insulating layers IL along the vertical direction VD are provided on the region of the substrate SUB between the two adjacent common source lines CSL. For example, the plurality of pillars “P” may be in contact with the substrate SUB through the plurality of insulating layers IL. In detail, a surface layer “S” of each pillar “P” may include a silicon material of a first type and may function as a channel. Meanwhile, an inner layer “I” of each pillar “P” may include an insulating material such as silicon oxide or an air gap.

In the region between the two adjacent common source lines CSL, a charge storage layer CS may be provided along exposed surfaces of the insulating layers IL, the pillars “P”, and the substrate SUB. The charge storage layer CS may include a gate insulating layer (or referred to as a “tunneling insulating layer”), a charge trap layer, and a blocking insulating layer. For example, the charge storage layer CS may have an oxide-nitride-oxide (ONO) structure. Furthermore, in the region between the two adjacent common source lines CSL, gate electrodes GE such as the selection lines GSL and SSL and the word lines WL1 to WL8 may be provided on an exposed surface of the charge storage layer CS.

Drains or drain contacts DR may be respectively provided on the plurality of pillars “P”. For example, each of the drains or drain contacts DR may include a silicon material which is doped with impurities of the second conductivity type. The bit lines BL1 to BL3 which extend in the first horizontal direction HD1 and are spaced apart from each other along the second horizontal direction HD2 as much as a specific distance may be provided on the drains DR.

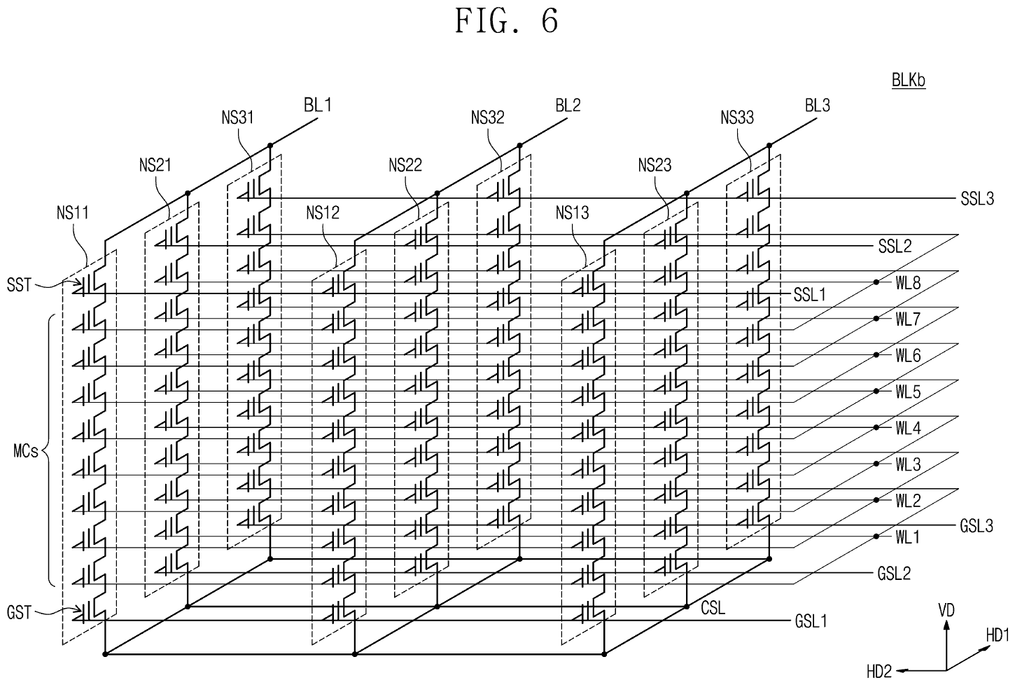

FIG. 6 is a circuit diagram illustrating an embodiment of a memory block of FIG. 4.

Referring to FIG. 6, a memory block BLKb may correspond to one of the plurality of memory blocks BLK1 to BLKz of FIG. 4. The memory block BLKb may include NAND strings NS11 to NS33, and each NAND string (e.g., NS11) may include a string selection transistor SST, a plurality of memory cells MCs, and a ground selection transistor GST which are connected in series. The transistors SST and GST and the memory cells MCs included in each NAND string may form a structure in which the transistors SST and GST and the memory cells MCs are stacked on a substrate in a vertical direction.

Word lines WL1 to WL8 may extend along a second horizontal direction, and bit lines BL1 to BL3 may extend along a first horizontal direction. The NAND strings NS11, NS21, and NS31 may be provided between the first bit line BL1 and a common source line CSL, the NAND strings NS12, NS22, and NS32 may be provided between the second bit line BL2 and the common source line CSL, and the NAND strings NS13, NS23, and NS33 may be provided between the third bit line BL3 and the common source line CSL. The string selection transistor SST may be connected to a corresponding one of string selection lines SSL1, SSL2, and SSL3, and the memory cells MCs may be respectively connected to the word lines WL1 to WL8. The ground selection transistor GST may be connected to a corresponding one of ground selection lines GSL1 to GSL3. The string selection transistor SST may be connected to a corresponding bit line, and the ground selection transistor GST may be connected to the common source line CSL. In an embodiment, the number of NAND strings, the number of word lines WLs, the number of bit lines BLs, the number of ground selection lines, and the number of string selection lines may be variously changed depending on embodiments.

FIG. 7 is a flowchart illustrating a method of operating a nonvolatile memory device according to an embodiment of the present disclosure.

An embodiment in which the channel equalization operation is performed when the suspend command is received during the execution of the program operation and the suspend command comes from the read request for a target memory cell (or a target memory block) from the external host device is illustrated in FIG. 7. For example, the embodiment may correspond to the case of intending to perform the read operation on the same memory block of a memory device in which the program operation is being performed.

Referring to FIG. 7, the program operation on the target memory cell T_MC may be started (S100).

In an embodiment, the program operation may include a plurality of program loops, and each of the plurality of program loops may include a bit line setup operation and a program execution operation. The bit line setup operation may refer to an operation of applying a ground voltage or a voltage greater than the ground voltage to bit lines associated with the target memory cell T_MC before the program execution operation, and the program execution operation may refer to an operation of applying a program voltage to the target memory cell T_MC.

The suspend command CMD_SUSPD according to a read request REQ_RD for the target memory block T_MBLK may be received before the bit line setup operation BLST of each of the plurality of program loops is completed (S110).

The resume command CMD_RSM according to the suspend command CMD_SUSPD may be received (S120).

Whether the suspend command CMD_SUSPD is a suspend command SUSPD_1 firstly received during the execution of the program operation may be determined (S130).

When the suspend command CMD_SUSPD is the suspend command SUSPD_1 firstly received during the execution of the program operation (Yes in operation S130), a channel equalization operation CH_EQ1 may be performed (S140), a resume verify operation RSM_VFY may be performed (S150), and the program loop PGM_LOOPK thus suspended may be again performed (S160).

When the suspend command CMD_SUSPD is not the suspend command SUSPD_1 firstly received during the execution of the program operation (No in operation S130), a channel equalization operation CH_EQ2 and a wrapping up operation WRUP may be performed (S170), and the program loop PGM_LOOPK thus suspended may be again performed (S180). For example, operation S170 and operation S180 may be performed when the suspend command CMD_SUSPD is received secondly or later during the execution of the program operation.

In an embodiment, operation S100, operation S110, operation S120, operation S130, operation S140, operation S150, operation S160, operation S170, and operation S180 may be performed by a nonvolatile memory device (e.g., 130 of FIG. 1 or 300 of FIG. 3) or a control circuit (e.g., 131 of FIG. 1 or 350 of FIG. 3).

In an embodiment, operation S100, operation S110, operation S120, operation S130, operation S140, operation S150, operation S160, operation S170, and operation S180 may be performed in each of the plurality of program loops constituting the program operation. For example, when the plurality of program loops are sequentially performed, operation S100, operation S110, operation S120, operation S130, operation S140, operation S150, operation S160, operation S170, and operation S180 may be repeatedly performed.

In an embodiment, the channel equalization operation CH_EQ1 and the channel equalization operation CH_EQ2 may be performed in different methods under different conditions.

For example, a voltage level of a selected word line associated with a target memory cell may be adjusted in the channel equalization operation CH_EQ1, and the voltage level of the selected word line may not be adjusted in the channel equalization operation CH_EQ2. For example, the control circuit may determine whether to adjust the voltage level of the selected word line in the channel equalization operation in response to whether the suspend command CMD_SUSPD according to the read request for the target memory block is firstly received during the execution of the program operation.

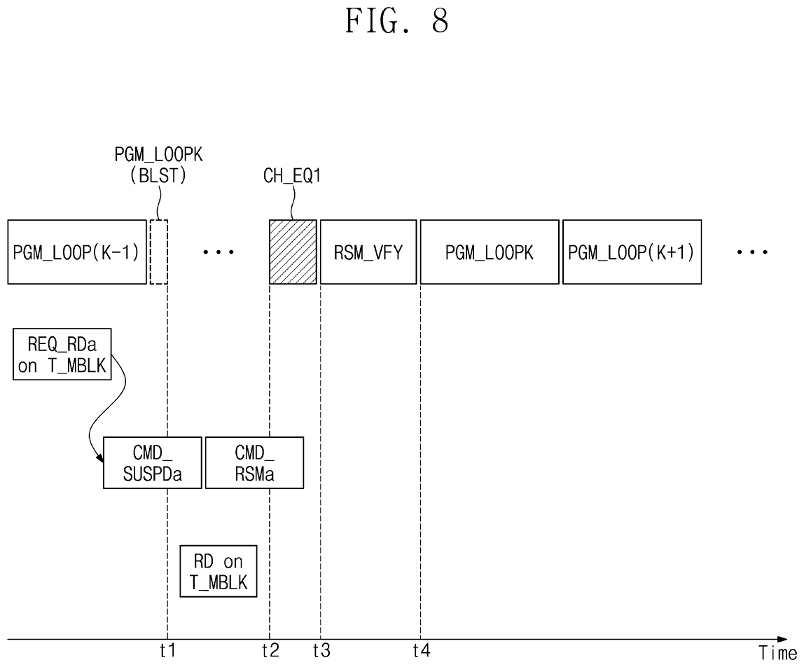

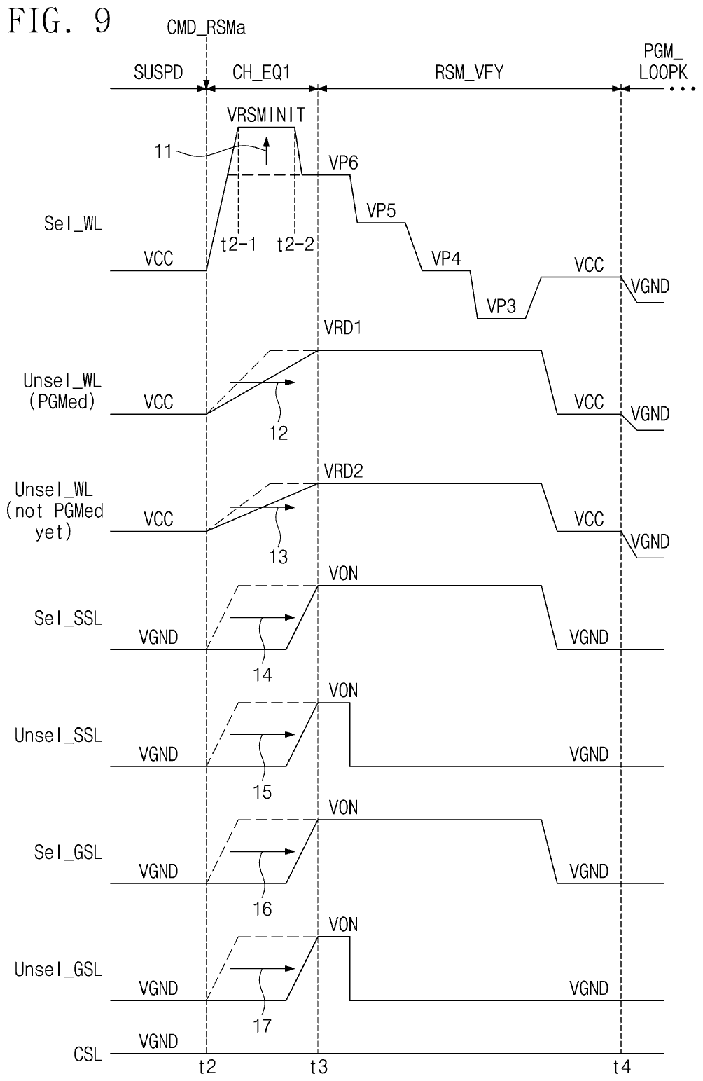

FIG. 8 is a diagram for describing an embodiment of a channel equalization operation of FIG. 7. FIG. 9 is a timing diagram for describing a channel equalization operation of FIG. 8.

The channel equalization operation CH_EQ1 of FIG. 7 will be described with reference to FIGS. 8 and 9.

Referring to FIG. 8, before a point in time t1, the program loop PGM_LOOPK-1 (e.g., the (K−1)-th program loop) for the target memory cell may be performed, and the bit line setup operation BLST of the program loop PGM_LOOPK (e.g., the K-th program loop) may be started.

Before the bit line setup operation BLST of the program loop PGM_LOOPK is completed, at the point in time t1, a suspend command CMD_SUSPDa according to a read request REQ_RDa for the target memory block T_MBLK may be received. For example, the suspend command CMD_SUSPDa may be a suspend command firstly received during the execution of the program operation.

A read operation RD on the target memory block T_MBLK may be performed, and at a point in time t2, a resume command CMD_RSMa according to the suspend command CMD_SUSPDa may be received.

After the point in time t2, the channel equalization operation CH_EQ1 may be performed; after a point in time t3, the resume verify operation RSM_VFY may be performed; after a point in time t4, the program loop PGM_LOOPK thus suspended and the program loop PGM_LOOP(K+1) (e.g., the (K+1)-th program loop) may be sequentially performed.

Referring to FIG. 9, before the point in time t2, voltage levels of a selected word line Sel_WL and unselected word lines Unsel_WL(PGMed) and Unsel_WL(not PGMed yet) associated with the target memory cell may maintain a voltage level VCC, and voltage levels of a selected string selection line Sel_SSL, an unselected string selection line Unsel_SSL, a selected ground selection line Sel_GSL, an unselected ground selection line Unsel_GSL, and the common source line CSL may maintain a ground voltage VGND.

Between the point in time t2 and the point in time t3, the voltage level of the selected word line Sel_WL may increase from the voltage level VCC to a resume verify initialization voltage level VRSMINIT, and the voltage level of the selected word line Sel_WL may maintain the resume verify initialization voltage level VRSMINIT during a time period from t2-1 to t2-2.

In an embodiment, the resume verify initialization voltage level VRSMINIT may be different from verify read voltages (e.g., VP6, VP5, VP4, and VP3 in FIG. 9) for the resume verify operation RSM_VFY. For example, the resume verify initialization voltage level VRSMINIT may be greater than voltage levels of the verify read voltages, and this is provided only as an example.

In an embodiment, in response to the suspend command CMD_SUSPDa according to the read request for the target memory block being firstly received during the execution of the program operation, the voltage level of the selected word line Sel_WL may be adjusted (e.g., 11), and points in time when the voltage levels of the unselected word lines Unsel_WL(PGMed) and Unsel_WL(not PGMed yet) associated with the target memory cell, the selected string selection line Sel_SSL, the unselected string selection line Unsel_SSL, the selected ground selection line Sel_GSL, and the unselected ground selection line Unsel_GSL are activated (e.g., activation time points) may be delayed (e.g., the magnitude of the delay may be represented by 12, 13, 14, 15, 16, and 17). For example, to perform the resume verify operation RSM_VFY, the point in time when the voltage levels of the unselected word lines Unsel_WL(PGMed) and Unsel_WL(not PGMed yet) increase to VRD1 or VRD2 and the point in time when the voltage levels of the string selection lines Sel_SSL and Unsel_SSL and the ground selection lines Sel_GSL and Unsel_GSL increase to VON may be delayed (i.e., may be delayed to a point in time after t2-2) while the voltage level of the selected word line Sel_WL maintains the resume verify initialization voltage level VRSMINIT.

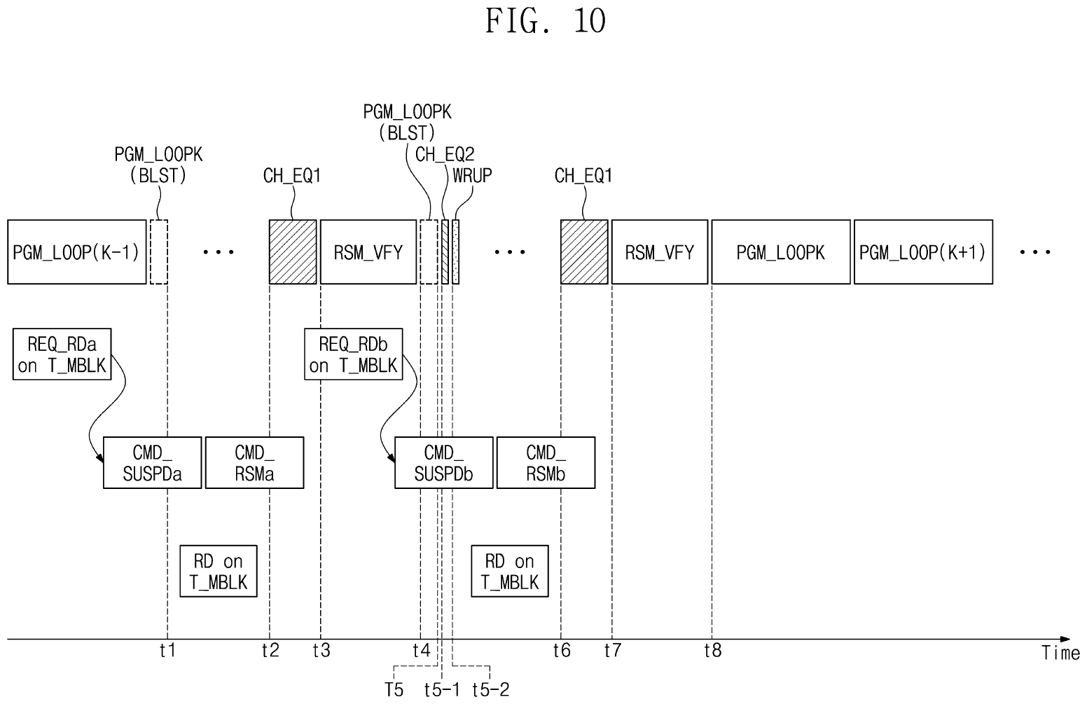

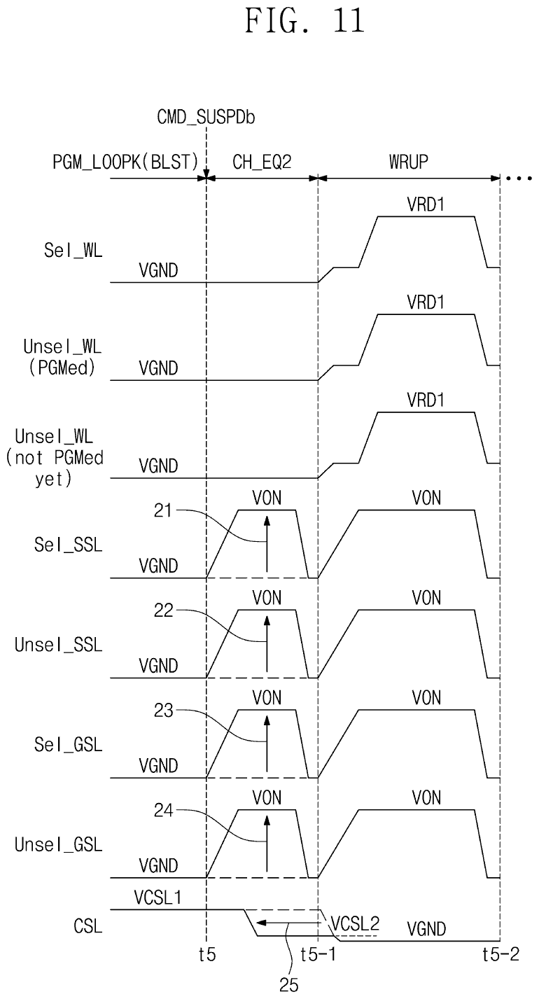

FIG. 10 is a diagram for describing an embodiment of a channel equalization operation of FIG. 7. FIG. 11 is a timing diagram for describing a channel equalization operation of FIG. 10.

The channel equalization operation CH_EQ2 of FIG. 7 is illustrated in FIGS. 10 and 11. Operations between points in times t1 and t4 are substantially the same as the operations described with reference to FIG. 8.

Referring to FIG. 10, the resume verify operation RSM_VFY on the target memory cell may be performed before the point in time t4, and the bit line setup operation BLST of the program loop PGM_LOOPK for the target memory cell may be started at the point in time t4.

Before the bit line setup operation BLST of the program loop PGM_LOOPK is completed, at the point in time t5, a suspend command CMD_SUSPDa according to a read request REQ_RDa for the target memory block T_MBLK may be received. For example, the suspend command CMD_SUSPDb may be a suspend command secondly or later received (e.g., a suspend command secondly received or a suspend command thirdly received) during the execution of the program operation.

After the point in time t5-1, the channel equalization operation CH_EQ2 may be performed; after the point in time t5-2, the wrapping up operation WRUP may be performed, and the read operation RD on the target memory block T_MBLK may be performed.

At the point in time t6, the resume command CMD_RSMb according to the suspend command CMD_SUSPDb may be received.

After the point in time t6, the channel equalization operation CH_EQ1 may be performed; after the point in time t7, the resume verify operation RSM_VFY may be performed; after the point in time t8, the program loop PGM_LOOPK thus suspended and the program loop PGM_LOOP(K+1) may be sequentially performed.

Referring to FIG. 11, before the point in time t5, voltage levels of the selected word line Sel_WL and the unselected word lines Unsel_WL(PGMed) and Unsel_WL(not PGMed yet) associated with the target memory cell, the selected string selection line Sel_SSL, the unselected string selection line Unsel_SSL, the selected ground selection line Sel_GSL, and the unselected ground selection line Unsel_GSL may maintain the ground level VGND, and the voltage level of the common source line CSL may maintain a voltage level VCSL1.

Between the points in time t5 and t5-1, the voltage levels of the selected word line Sel_WL and the unselected word lines Unsel_WL(PGMed) and Unsel_WL(not PGMed yet) may maintain the ground level VGND. The voltage levels of the selected string selection line Sel_SSL, the unselected string selection line Unsel_SSL, the selected ground selection line Sel_GSL, and the unselected ground selection line Unsel_GSL may increase to a voltage level VON, may then maintain the voltage level VON, and may then decrease to the ground level VGND. The voltage level of the common source line CSL may decrease to a voltage level VCSL2 and may then maintain the voltage level VCSL2.

In an embodiment, the voltage level VON may be a voltage level for turning on a relevant transistor. The voltage level VCSL2 may be lower than the voltage level VCSL1 and may be higher than the ground level VGND, and this is provided only as an example.

In an embodiment, in response to the suspend command CMD_SUSPDb according to the read request for the target memory block being a suspend command secondly or later received during the execution of the program operation, the voltage levels of the selected word line Sel_WL and the unselected word line Unsel_WL may be maintained, and the voltage levels of the selected string selection line Sel_SSL, the unselected string selection line Unsel_SSL, the selected ground selection line Sel_GSL, and the unselected ground selection line Unsel_GSL may be adjusted. The voltage level of the common source line CSL may also be adjusted. For example, as the voltage levels of the selected string selection line Sel_SSL, the unselected string selection line Unsel_SSL, the selected ground selection line Sel_GSL, and the unselected ground selection line Unsel_GSL are adjusted, string selection transistors and ground selection transistors corresponding thereto may be turned on (e.g., 21, 22, 23, and 24), and thus, the voltage level of the common source line CSL may decrease to the voltage level VCSL2 and may then maintain the voltage level VCSL2 (i.e., the falling time point of the voltage level of the common source line CSL may be advanced (e.g., 25)).

FIG. 12 is a flowchart illustrating a method of operating a nonvolatile memory device according to an embodiment of the present disclosure.

An embodiment in which the channel equalization operation is performed when the suspend command is received during the execution of the program operation and the suspend command comes from the read request for a non-target memory cell (or a non-target memory block) from the external host device is illustrated in FIG. 12. For example, the embodiment may correspond to the case of intending to perform the read operation on a memory block different from a memory device in which the program operation is being performed.

Referring to FIG. 12, the program operation on the target memory cell T_MC may be started (S300).

The suspend command CMD_SUSPD according to the read request REQ_RD for the non-target memory block N_T_MBLK may be received before the bit line setup operation BLST of each of the plurality of program loops is completed (S310).

The resume command CMD_RSM according to the suspend command CMD_SUSPD may be received (S320).

Whether the suspend command CMD_SUSPD is a suspend command SUSPD_1 firstly received during the execution of the program operation may be determined (S330).

When the suspend command CMD_SUSPD is the suspend command SUSPD_1 firstly received during the execution of the program operation (Yes in operation S330), the resume verify operation RSM_VFY may be performed (S350), and the program loop PGM_LOOPK thus suspended may be again performed (S360).

When the suspend command CMD_SUSPD is not the suspend command SUSPD_1 firstly received during the execution of the program operation (No in operation S330), the channel equalization operation CH_EQ2 and the wrapping up operation WRUP may be performed (S370), and the program loop PGM_LOOPK thus suspended may be again performed (S380). For example, operation S370 and operation S380 may be performed when the suspend command CMD_SUSPD is secondly or later received during the execution of the program operation.

In an embodiment, operation S300, operation S310, operation S320, operation S330, operation S350, operation S360, operation S370, and operation S380 may be performed by a nonvolatile memory device (e.g., 130 of FIG. 1 or 300 of FIG. 3) or a control circuit (e.g., 131 of FIG. 1 or 350 of FIG. 3).

In an embodiment, the channel equalization operation CH_EQ1 described with reference to FIG. 7 may not be performed in the embodiment described with reference to FIG. 12, and the channel equalization operation CH_EQ2 may be substantially the same as the channel equalization operation CH_EQ2 described with reference to FIG. 7.

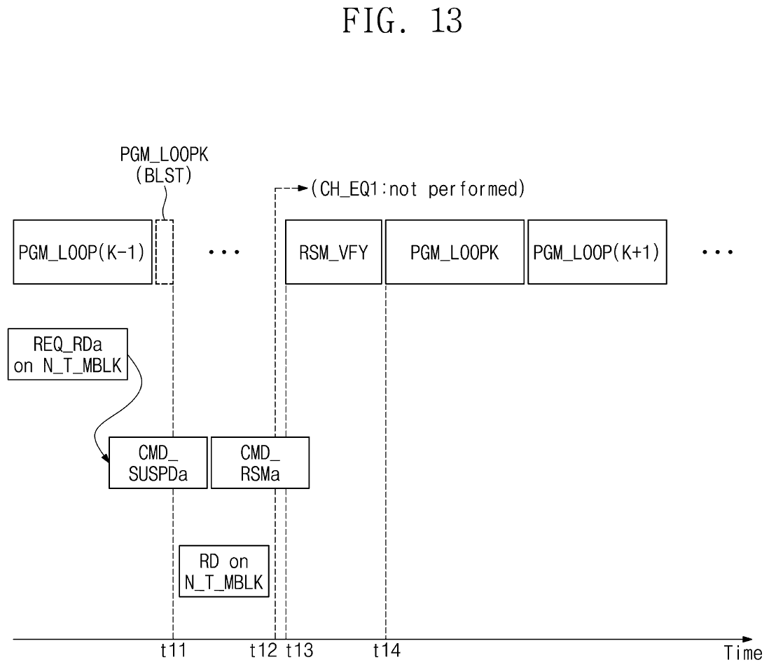

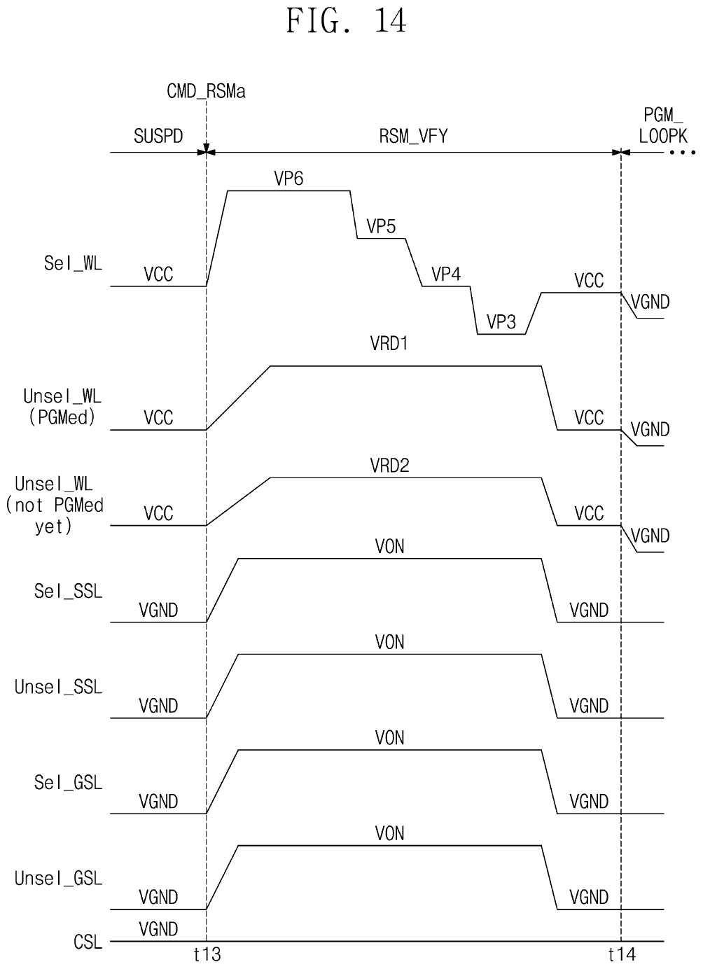

FIG. 13 is a diagram for describing an embodiment in which a channel equalization operation of FIG. 12 is not performed. FIG. 14 is a timing diagram for describing non-execution of a channel equalization operation of FIG. 13.

An embodiment in which the channel equalization operation CH_EQ1 of FIG. 7 is not performed is illustrated in FIGS. 13 and 14.

Referring to FIGS. 8 and 13, the channel equalization operation CH_EQ1 illustrated in FIG. 8 may not be performed in the embodiment of FIG. 13. In the embodiment described with reference to FIG. 8, because the suspend command CMD_SUSPDa corresponds to the case of perform the resume operation after performing the read operation on a target memory block including a target memory cell on which the program operation is being performed, the need to perform the channel equalization operation may be relatively high; however, in the embodiment of FIG. 13, because the suspend command CMD_SUSPDa corresponds to the case of perform the resume operation after performing the read operation on a non-target memory block including a non-target memory cell on which the program operation is not performed, the need to perform the channel equalization operation may be relatively low. According to the embodiment of FIG. 13 in which the channel equalization operation CH_EQ1 is not performed, power consumption due to the iteration of suspend and resume operations may be reduced.

Referring to FIGS. 9 and 14, the operations (e.g., 11, 12, 13, 14, 15, 16, and 17) described with reference to FIG. 9 may not be performed in the embodiment of FIG. 14.

In an embodiment, in response to the suspend command CMD_SUSPDa according to the read request for the non-target memory block being firstly received during the execution of the program operation, the voltage level of the selected word line Sel_WL may not be adjusted, and points in time when the voltage levels of the unselected word lines Unsel_WL(PGMed) and Unsel_WL(not PGMed yet) associated with the target memory cell, the selected string selection line Sel_SSL, the unselected string selection line Unsel_SSL, the selected ground selection line Sel_GSL, and the unselected ground selection line Unsel_GSL are activated may not be delayed.

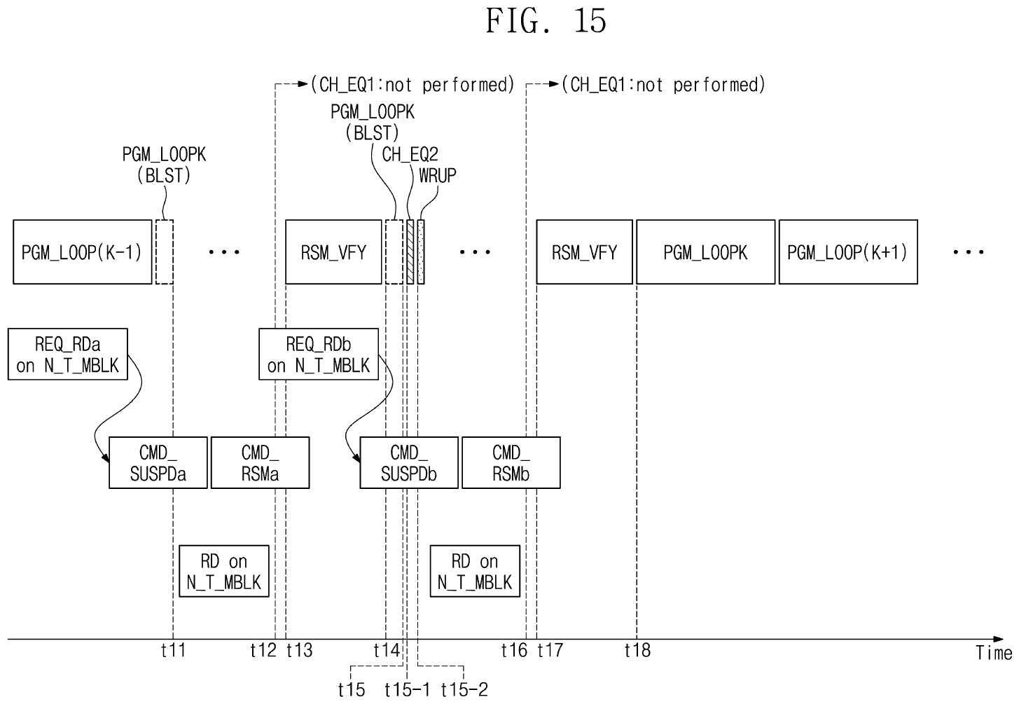

FIG. 15 is a diagram for describing an embodiment of a channel equalization operation of FIG. 12.

The channel equalization operation CH_EQ2 of FIG. 12 is illustrated in FIG. 15. Operations between points in times t11 and t14 are substantially the same as the operations described with reference to FIG. 13. Operations at points in time t14, t15, t15-1, t15-2, t17, and t18 respectively correspond to the operations at the points in time t4, t5, t5-1, 5-2, 7, and t8 described with reference to FIG. 10, and the embodiment illustrated in FIG. 15 is substantially the same as the embodiment illustrated in FIG. 10 except that the channel equalization operation CH_EQ1 is not performed. Thus, additional description will be omitted to avoid redundancy.

FIG. 16 is a flowchart for describing an embodiment of a channel equalization operation of FIG. 12.

Referring to FIGS. 12 and 16, operation S370 and operation S380 of FIG. 12 may respectively correspond to operation S371 and operation S380 of FIG. 16. Accordingly, operation S371 may be performed when the suspend command CMD_SUSPD is not the suspend command SUSPD_1 firstly received during the execution of the program operation (No in operation S330); in this case, only the channel equalization operation CH_EQ2 may be performed, and the wrapping up operation WRUP may not be performed (S371).

In an embodiment, the wrapping up operation WRUP which is not performed in operation S371 may mean an operation which is performed after the channel equalization operation CH_EQ2 described with reference to FIGS. 10, 11, and 15 and may be distinguished from the wrapping up operation for a post operation on a target memory cell after the last program loop PGM_LOOPN described with reference to FIG. 2A. As in the above description given with reference to FIG. 13, that is, to be similar to the case where the channel equalization operation is not performed, because it corresponds to the case of performing the read operation on not the target memory block but the non-target memory block, compared to the case of perform the wrapping up operation before the read operation on the target memory block is performed, the need to perform the wrapping up operation may be relatively low, and as the wrapping up operation is not performed, power consumption due to the iteration of the suspend and resume operations may be reduced.

After operation S371, the program loop PGM_LOOPK thus suspended may be again performed (S380).

FIG. 17 is a timing diagram for describing a channel equalization operation of FIG. 16.

Referring to FIGS. 11 and 17, the wrapping up operation WRUP illustrated in FIG. 11 may not be performed in the embodiment of FIG. 17.

In an embodiment, the voltage levels of the selected word line Sel_WL and the unselected word lines Unsel_WL(PGMed) and Unsel_WL(not PGMed yet) may be adjusted to the voltage level VCC after the channel equalization operation CH_EQ2 is performed and may then maintain the voltage level VCC (e.g., 41, 42, and 43). After the channel equalization operation CH_EQ2 is performed, the voltage levels of the selected string selection line Sel_SSL, the unselected string selection line Unsel_SSL, the selected ground selection line Sel_GSL, and the unselected ground selection line Unsel_GSL may maintain the ground level VGND or may decrease to the ground level VGND and may then maintain the ground level VGND (e.g., 44, 45, 46, and 47). For example, the voltage level VCC may be a reference voltage level for a normal operation of a memory cell array, but this is provided only as an example.

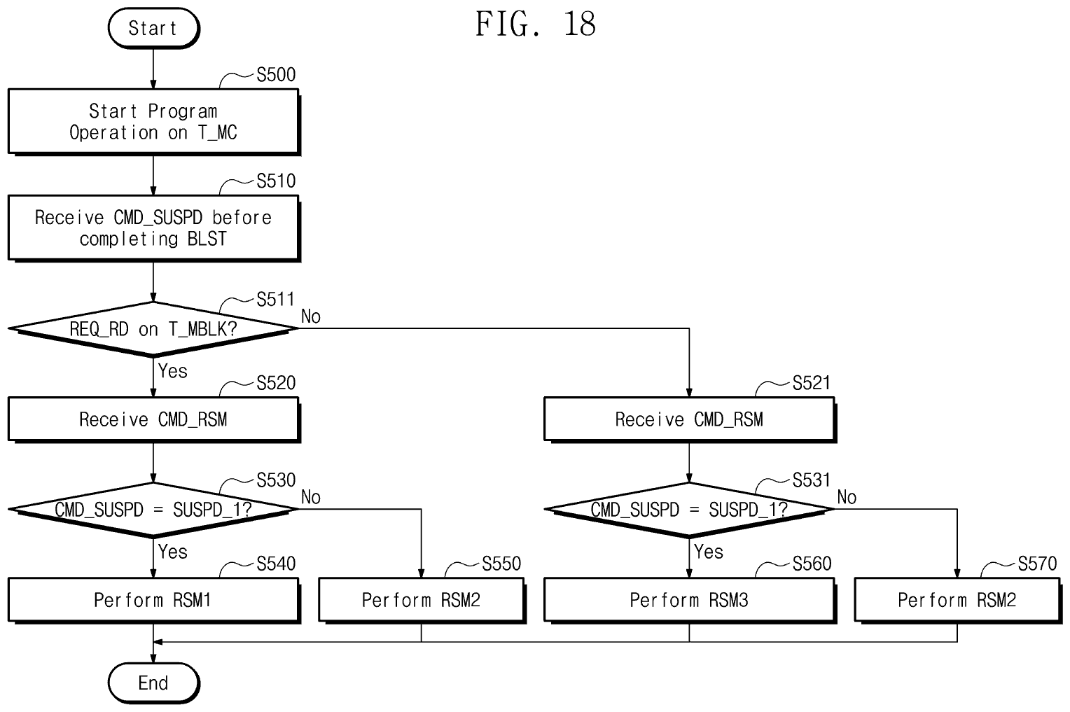

FIG. 18 is a flowchart illustrating a method of operating a nonvolatile memory device according to an embodiment of the present disclosure.

The embodiments described with reference to FIGS. 7 and 12 are integrally illustrated in FIG. 18.

Referring to FIG. 18, the program operation on the target memory cell T_MC may be started (S500).

In an embodiment, the program operation may include a plurality of program loops, and each of the plurality of program loops may include a bit line setup operation and a program execution operation.

The suspend command CMD_SUSPD may be received before the bit line setup operation BLST of each of the plurality of program loops is completed (S510).

Whether the suspend command CMD_SUSPD is a suspend command according to the read request REQ_RD for the target memory block T_MBLK may be determined (S511).

When the suspend command CMD_SUSPD is the suspend command according to the read request REQ_RD for the target memory block T_MBLK (Yes in operation S511), the resume command CMD_RSM according to the suspend command CMD_SUSPD may be received (S520), and whether the suspend command CMD_SUSPD is the suspend command SUSPD_1 firstly received during the execution of the program operation may be determined (S530).

When the suspend command CMD_SUSPD is the suspend command SUSPD_1 firstly received during the execution of the program operation (Yes in operation S530), a resume operation RSM1 may be performed (S540). When the suspend command CMD_SUSPD is a suspend command secondly or later received during the execution of the program operation (No in operation S530), a resume operation RSM2 may be performed (S550).

When the suspend command CMD_SUSPD is not the suspend command according to the read request REQ_RD for the target memory block T_MBLK (No in operation S511), the resume command CMD_RSM according to the suspend command CMD_SUSPD may be received (S521), and whether the suspend command CMD_SUSPD is the suspend command SUSPD_1 firstly received during the execution of the program operation may be determined (S531).

When the suspend command CMD_SUSPD is the suspend command SUSPD_1 firstly received during the execution of the program operation (Yes in operation S531), a resume operation RSM3 may be performed (S560). When the suspend command CMD_SUSPD is a suspend command secondly or later received during the execution of the program operation (No in operation S531), a resume operation RSM2 may be performed (S570).

In an embodiment, the resume operation RSM1 may be an operation of performing the channel equalization operation CH_EQ1 described with reference to FIG. 7 or 8. The resume operation RSM2 may be an operation of performing the channel equalization operation CH_EQ2 described with reference to FIGS. 11 and 15. The resume operation RSM3 may be an operation in which the channel equalization operation CH_EQ1 described with reference to FIG. 13 is not performed.

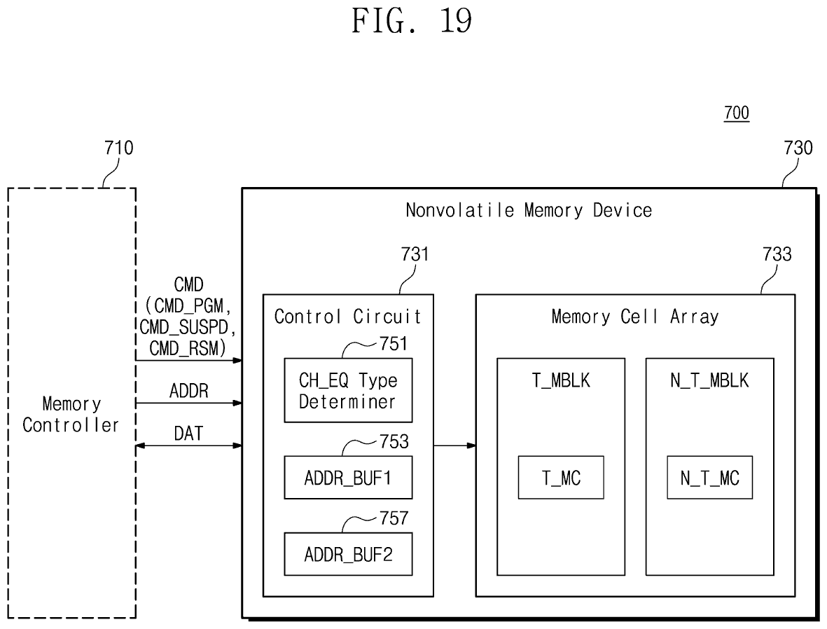

FIG. 19 is a block diagram illustrating a memory system including a nonvolatile memory device according to an embodiment of the present disclosure.

Referring to FIG. 19, a memory system 700 may include a memory controller 710 and a nonvolatile memory device 730. The nonvolatile memory device 730 may include a control circuit 731 and a memory cell array 733. The memory system 700 illustrated in FIG. 17 is substantially the same as the memory system 100 illustrated in FIG. 1 except that the control circuit 731 further includes a channel equalization type determiner 751, an address buffer (ADDR_BUF1) 753, and an address buffer (ADDR_BUF2) 757.

The address buffers 753 and 757 may store addresses associated with a program operation (or a program request from the external host device) and a read operation (or a read request from the external host device) of the nonvolatile memory device 730. For example, the address buffer 753 may store first addresses associated with the program operation, and the address buffer 757 may store second addresses associated with the read operation.

The channel equalization type determiner 751 may determine whether the suspend command CMD_SUSPD comes from the read request for a target memory block, based on the addresses stored in the address buffers 753 and 757 and the resume command CMD_RSM.

In an embodiment, the determination by the channel equalization type determiner 751 may be associated with operation S110 of FIG. 7 and operation S310 of FIG. 12 and may correspond to the determination according to operation S511 of FIG. 18. For example, when the first addresses are identical to the second addresses and the resume command CMD_RSM is received from the memory controller 710, the channel equalization type determiner 751 may determine that the suspend command CMD_SUSPD is a suspend command according to the read request for the target memory block.

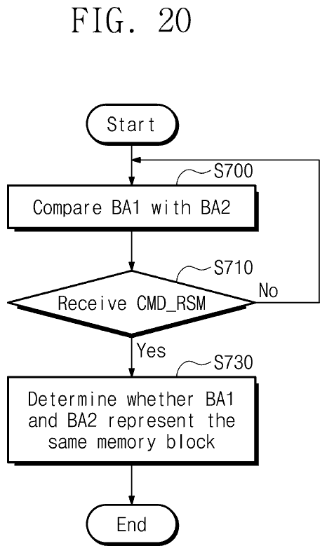

FIG. 20 is a flowchart illustrating an operation of a control circuit of FIG. 19.

Referring to FIG. 20, first addresses BA1 may be compared with second addresses BA2 (S700).

Whether the resume command CMD_RSM is received may be determined (S710).

When the resume command CMD_RSM is received (Yes in operation S710), the first addresses BA1 and the second addresses BA2 may be determined as representing the same memory block (S730).

When the resume command CMD_RSM is not received (No in operation S710), the first addresses BA1 and the second addresses BA2 may be continuously compared (S700).

In an embodiment, a result according to the comparison in operation S700 may be a temporary determination associated with whether the first addresses BAL and the second addresses BA2 represent the same memory block, and the determination in operation S730 may be a final determination associated with whether the first addresses BA1 and the second addresses BA2 represent the same memory block. For example, all the addresses stored in the address buffers 753 and 757 of FIG. 19 until a point in time when the resume command CMD_RSM is received may be used as data for determining whether a suspend command is a suspend command according to a read request for a target memory block, according to embodiments of the present disclosure.

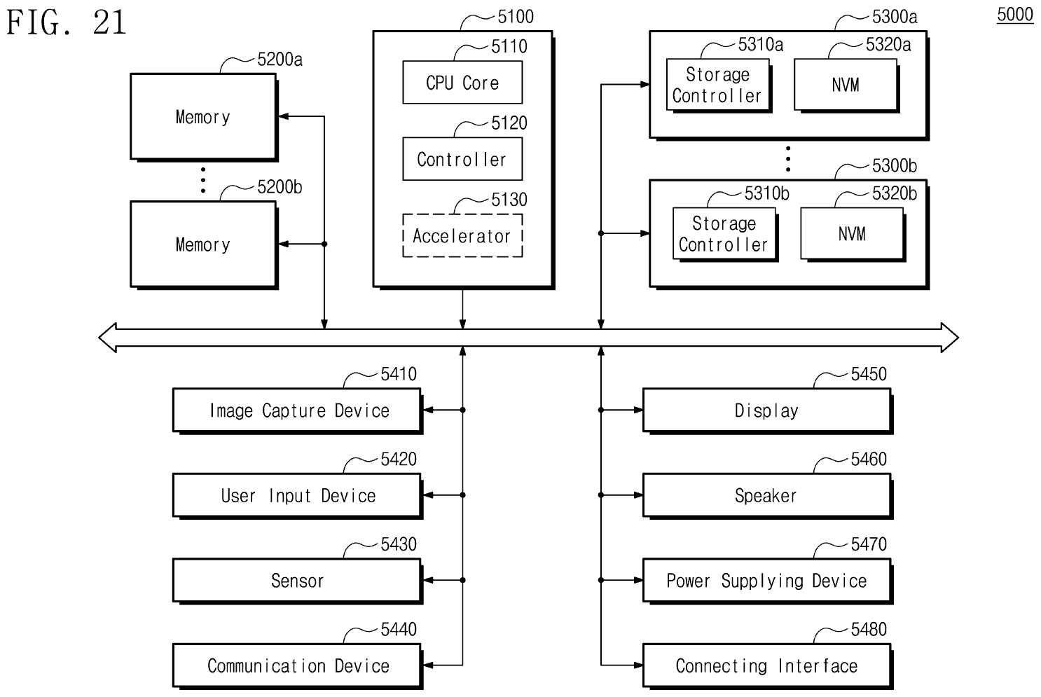

FIG. 21 is a diagram of a system 5000 to which a nonvolatile memory device is applied, according to an embodiment. The system 5000 of FIG. 21 may basically be a mobile system, such as a portable communication terminal (e.g., a mobile phone), a smartphone, a tablet personal computer (PC), a wearable device, a healthcare device, or an Internet of things (IOT) device. However, the system 5000 of FIG. 21 is not necessarily limited to the mobile system and may be a PC, a laptop computer, a server, a media player, or an automotive device (e.g., a navigation device).

Referring to FIG. 21, the system 5000 may include a main processor 5100, memories (e.g., 5200a and 5200b), and storage devices (e.g., 5300a and 5300b). In addition, the system 5000 may include at least one of an image capturing device 5410, a user input device 5420, a sensor 5430, a communication device 5440, a display 5450, a speaker 5460, a power supplying device 5470, and a connecting interface 5480.

The main processor 5100 may control all operations of the system 5000, more specifically, operations of other components included in the system 5000. The main processor 5100 may be implemented as a general-purpose processor, a dedicated processor, or an application processor.

The main processor 5100 may include at least one CPU core 5110 and further include a controller 5120 configured to control the memories 5200a and 5200b and/or the storage devices 5300a and 5300b. In some embodiments, the main processor 5100 may further include an accelerator 5130, which is a dedicated circuit for a high-speed data operation, such as an artificial intelligence (AI) data operation. The accelerator 5130 may include a graphics processing unit (GPU), a neural processing unit (NPU) and/or a data processing unit (DPU) and be implemented as a chip that is physically separate from the other components of the main processor 5100.

The memories 5200a and 5200b may be used as main memory devices of the system 5000. Although each of the memories 5200a and 5200b may include a volatile memory, such as static random access memory (SRAM) and/or dynamic RAM (DRAM), each of the memories 5200a and 5200b may include non-volatile memory, such as a flash memory, phase-change RAM (PRAM) and/or resistive RAM (RRAM). The memories 5200a and 5200b may be implemented in the same package as the main processor 5100.

The storage devices 5300a and 5300b may serve as non-volatile storage devices configured to store data regardless of whether power is supplied thereto, and have larger storage capacity than the memories 5200a and 5200b. The storage devices 5300a and 5300b may respectively include storage controllers (STRG CTRL) 5310a and 5310b and NVM (Non-Volatile Memory) s 5320a and 5320b configured to store data via the control of the storage controllers 5310a and 5310b. Although the NVMs 5320a and 5320b may include flash memories having a two-dimensional (2D) structure or a three-dimensional (3D) V-NAND structure, the NVMs 5320a and 5320b may include other types of NVMs, such as PRAM and/or RRAM.

The storage devices 5300a and 5300b may be physically separated from the main processor 5100 and included in the system 5000 or implemented in the same package as the main processor 5100. In addition, the storage devices 5300a and 5300b may have types of solid-state devices (SSDs) or memory cards and be removably combined with other components of the system 5000 through an interface, such as the connecting interface 5480 that will be described below. The storage devices 5300a and 5300b may be devices to which a standard protocol, such as a universal flash storage (UFS), an embedded multi-media card (eMMC), or a non-volatile memory express (NVMe), is applied, without being limited thereto.

The image capturing device 5410 may capture still images or moving images. The image capturing device 5410 may include a camera, a camcorder, and/or a webcam.

The user input device 5420 may receive various types of data input by a user of the system 5000 and include a touch pad, a keypad, a keyboard, a mouse, and/or a microphone.

The sensor 5430 may detect various types of physical quantities, which may be obtained from the outside of the system 5000, and convert the detected physical quantities into electric signals. The sensor 5430 may include a temperature sensor, a pressure sensor, an illuminance sensor, a position sensor, an acceleration sensor, a biosensor, and/or a gyroscope sensor.

The communication device 5440 may transmit and receive signals between other devices outside the system 5000 according to various communication protocols. The communication device 5440 may include an antenna, a transceiver, and/or a modem.

The display 5450 and the speaker 5460 may serve as output devices configured to respectively output visual information and auditory information to the user of the system 5000.

The power supplying device 5470 may appropriately convert power supplied from a battery embedded in the system 5000 and/or an external power source, and supply the converted power to each of components of the system 5000.

The connecting interface 5480 may provide connection between the system 5000 and an external device, which is connected to the system 5000 and capable of transmitting and receiving data to and from the system 5000. The connecting interface 5480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In an embodiment, the storage devices 5300a and 5300b may be the memory systems 100 and 700 described with reference to FIGS. 1, 19, etc. The storage devices 5300a and 5300b may perform the channel equalization operations or may selectively perform the wrapping up operation, depending on the method of operating the nonvolatile memory device according to embodiments of the present disclosure.

A nonvolatile memory device according to embodiments of the present disclosure may remove the voltage imbalance caused in a channel voltage of a cell string due to the iteration of suspend and resume operations according to a read request from a host device while performing a program operation. Accordingly, it may be possible to prevent the decrease in the reliability of data stored in the nonvolatile memory device and to reduce power consumption.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A nonvolatile memory device comprising:
a memory cell array including a target memory block including a target memory cell and a non-target memory block including a non-target memory cell; and
a control circuit configured to:
start a program operation on the target memory cell, wherein the program operation includes a plurality of program loops each including a bit line setup operation and a program execution operation; and
perform a channel equalization operation of equalizing a channel voltage of a cell string associated with the target memory cell, in response to receiving a suspend command according to a read request for one of the target memory block and the non-target memory block before the bit line setup operation of each of the plurality of program loops is completed and receiving a resume command according to the suspend command.

2. The nonvolatile memory device of claim 1, wherein, in response to whether the suspend command according to the read request for the target memory block is firstly received during execution of the program operation, the control circuit is configured to determine whether to adjust a voltage level of a selected word line associated with the target memory cell in the channel equalization operation.

3. The nonvolatile memory device of claim 2, wherein, in response to that the suspend command according to the read request for the target memory block is firstly received during the execution of the program operation, the control circuit is configured to adjust the voltage level of the selected word line and is configured to delay activation time points of voltage levels of an unselected word line associated with the target memory cell, a string selection line, and a ground selection line.

4. The nonvolatile memory device of claim 3, wherein the control circuit is configured to adjust the voltage level of the selected word line to a resume verify initialization voltage different from verify read voltages for a resume verify operation.

5. The nonvolatile memory device of claim 4, wherein a voltage level of the resume verify initialization voltage is greater than voltage levels of the verify read voltages.

6. The nonvolatile memory device of claim 5, wherein, while the voltage level of the selected word line maintains the resume verify initialization voltage, the control circuit is configured to delay the activation time point of the voltage level of the unselected word line.

7. The nonvolatile memory device of claim 3, wherein, in response to the suspend command according to the read request for the target memory block being received secondly or later during the execution of the program operation, the control circuit is configured to maintain the voltage levels of the selected word line and the unselected word line and is configured to adjust the voltage levels of the string selection line and the ground selection line.

8. The nonvolatile memory device of claim 7, wherein the control circuit is configured to adjust the voltage levels of the string selection line and the ground selection line such that a string selection transistor associated with the string selection line and a ground selection transistor connected to the ground selection line are turned on.

9. The nonvolatile memory device of claim 7, wherein, in response to the suspend command according to the read request for the target memory block being received secondly or later during the execution of the program operation, the control circuit is further configured to adjust a voltage level of a common source line connected to the target memory cell.

10. The nonvolatile memory device of claim 1, wherein, in response to the suspend command according to the read request for the non-target memory block being received secondly or later during the execution of the program operation, the control circuit is configured to maintain a voltage level of a selected word line associated with the target memory cell and a voltage level of an unselected word line and is configured to adjust voltage levels of a string selection line and a ground selection line associated with the target memory cell.

11. The nonvolatile memory device of claim 1, wherein, after the suspend command is received, the control circuit is further configured to perform a wrapping up operation associated with the target memory cell before a read operation based on the read request is performed.

12. The nonvolatile memory device of claim 11, in response to that the suspend command according to the read request for the non-target memory block is received secondly or later during execution of the program operation, the control circuit is not configured to perform the wrapping up operation.

13. The nonvolatile memory device of claim 1, wherein the control circuit includes:
address buffers configured to store first addresses associated with the program operation and second addresses associated with the read request; and
a channel equalization type determiner configured to determine whether the suspend command is a suspend command according to a read request for the target memory block, based on the first addresses, the second addresses, and the resume command.

14. The nonvolatile memory device of claim 13, wherein, in response to the first addresses being identical to the second addresses and the resume command is received, the channel equalization type determiner is configured to determine that the suspend command is the suspend command according to the read request for the target memory block.

15. A method of operating a nonvolatile memory device, the method comprising:
starting a program operation on a target memory cell, wherein the program operation includes a plurality of program loops each including a bit line setup operation and a program execution operation;
receiving a suspend command according to a read request for one of a target memory block including the target memory cell and a non-target memory block including a non-target memory cell before the bit line setup operation of each of the plurality of program loops is completed;
receiving a resume command according to the suspend command; and
performing a channel equalization operation of equalizing a channel voltage of a cell string associated with the target memory cell in response to the suspend command and the resume command.

16. The method of claim 15, further comprising:
determining whether the suspend command is a suspend command according to a read request for the target memory block, based on first addresses associated with the program operation, second addresses associated with the read request, and the resume command.

17. The method of claim 15, wherein the performing of the channel equalization operation includes:
determining whether to adjust a voltage level of a selected word line associated with the target memory cell in the channel equalization operation in response to whether the suspend command according to the read request for the target memory block is firstly received during execution of the program operation.

18. The method of claim 17, wherein the performing of the channel equalization operation further includes:
maintaining a voltage level of the selected word line associated with the target memory cell and a voltage level of an unselected word line and adjusting voltage levels of a string selection line and a ground selection line associated with the target memory cell, in response to the suspend command according to the read request for the target memory block being received secondly or later during the execution of the program operation.

19. The method of claim 15, further comprising:
not performing a wrapping up operation associated with the target memory cell, in response to the suspend command according to the read request for the non-target memory block being received secondly or later during execution of the program operation.

20. A nonvolatile memory device comprising:
a memory cell array including a target memory block including a target memory cell and a non-target memory block including a non-target memory cell;
an address decoder connected to the memory cell array through a string selection line, a plurality of word lines, and a ground selection line; and
a control circuit configured to:
start a program operation on the target memory cell, wherein the program operation includes a plurality of program loops each including a bit line setup operation; and
perform a channel equalization operation of equalizing a channel voltage of a cell string associated with the target memory cell by controlling voltage levels of the string selection line, the plurality of word lines, and the ground selection line, in response to receiving a suspend command according to an operation request for one of the target memory block and the non-target memory block before the bit line setup operation of each of the plurality of program loops is completed and receiving a resume command according to the suspend command.
